(19) United States
(12) Patent Application Publication
(10) Pub. No.: US 2022/0375730 A1
(43) Pub. Date: Nov. 24, 2022

(54) PLASMA PROCESSING APPARATUS

(71) Applicant: TOKYO ELECTRON LIMITED, Tokyo (JP)

(72) Inventor: Ryota SAKANE, Miyagi (JP)

(73) Assignee: TOKYO ELECTRON LIMITED, Tokyo (JP)

(21) Appl. No.: 17/747,861

(22) Filed: May 18, 2022

(30) Foreign Application Priority Data
May 19, 2021 (JP) 2021-084957

(51) Int. Cl. H01J 37/32

(52) U.S. Cl. CPC H01J 37/32651; H01J 37/32715; H01J 2237/0264; H01J 2237/3321

(57) ABSTRACT

A plasma processing apparatus includes a plasma processing chamber whose wall has a multi-layer structure including a layer made of a material having a permeability higher than a permeability of aluminum and a loading/unloading port disposed on the wall of the plasma processing chamber to load/unload a substrate into/from the plasma processing chamber. The plasma processing apparatus includes a substrate support disposed in the plasma processing chamber.

### CROSS-REFERENCE TO RELATED APPLICATIONS

This application claims priority to Japanese Patent Application No. 2021-084957 filed on May 19, 2021, the entire contents of which are incorporated herein by reference.

### TECHNICAL FIELD

The present disclosure relates to a plasma processing apparatus.

### BACKGROUND

In a substrate processing apparatus, it is proposed to provide a magnetic shield outside a processing chamber in order to reduce the influence of an external magnetic field and improve uniformity of plasma (see, e.g., Japanese Patent Application Publication No. 2004-022988). Further, it is proposed to use a permeable material such as Permalloy or the like as a magnetic shield (see, e.g., Japanese Patent Application Publication No. 2005-249658).

### SUMMARY

The present disclosure provides a plasma processing apparatus capable of shielding an environmental magnetic field including terrestrial magnetism and magnetism from other devices.

One aspect of the present disclosure provides a plasma processing apparatus including a plasma processing chamber whose wall has a multi-layer structure including a layer made of a material having a permeability higher than a permeability of aluminum, a loading/unloading port disposed on the wall of the plasma processing chamber to load/unload a substrate into/from the plasma processing chamber, and a substrate support disposed in the plasma processing chamber.

### BRIEF DESCRIPTION OF THE DRAWINGS

The objects and features of the present disclosure will become apparent from the following description of embodiments, given in conjunction with the accompanying drawings, in which:

FIG. 1 shows an example of a plasma processing apparatus according to an embodiment of the present disclosure;

FIG. 2 schematically shows an example of a structure of a shield member in the present embodiment;

FIG. 3 schematically shows an example of the structure of the shield member in the present embodiment;

FIG. 4 schematically shows an example of the structure of the shield member in the present embodiment;

FIG. 5 schematically shows an example of the structure of the shield member in the present embodiment;

FIG. 6 schematically shows an example of the structure of the shield member in the present embodiment;

FIG. 7 schematically shows an example of the structure of the shield member in the present embodiment; and

FIG. 8 shows an example of a magnetic shield cover in the present embodiment.

### DETAILED DESCRIPTION

Hereinafter, an embodiment of a plasma processing apparatus of the present disclosure will be described in detail with reference to the accompanying drawings. The following embodiment is not intended to limit the present disclosure.

Recently, with the progress of miniaturization of semiconductor devices, the influence of terrestrial magnetism on plasma cannot be ignored. Further, in a substrate processing system including a plurality of plasma processing apparatuses, plasma may be deflected due to the influence of a magnetic field generated by another adjacent plasma processing apparatus. On the other hand, although it is considered to cover the plasma processing apparatus with a magnetic shield, it is difficult to cover a loading/unloading port for a substrate with the magnetic shield. Further, when the entire substrate processing system is covered with a magnetic shield, it is difficult to shield a magnetic field generated by another plasma processing apparatus. Therefore, it is expected to shield an environmental magnetic field including terrestrial magnetism and magnetism from other devices.

(Configuration of Plasma Processing Apparatus)

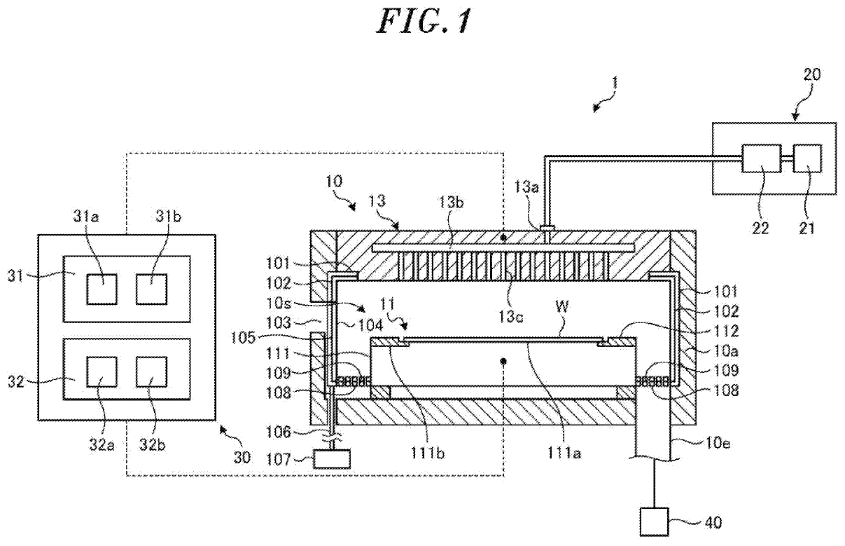

Hereinafter, a configuration example of a capacitively coupled plasma processing apparatus will be described as an example of a plasma processing apparatus 1. FIG. 1 shows an example of a plasma processing apparatus according to an embodiment of the present disclosure. As shown in FIG. 1, a capacitively coupled plasma processing apparatus 1 includes a plasma processing chamber 10, a gas supplier 20, a power supply 30, and an exhaust system 40. The plasma processing apparatus 1 further includes a substrate support 11 and a gas inlet portion. The gas inlet portion is configured to introduce at least one processing gas into the plasma processing chamber 10. The gas inlet portion includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically isolated from the plasma processing chamber 10.

The plasma processing chamber 10 has a shield member 101 at an inner side of a sidewall 10a. An upper portion of the shield member 101 extends inward in a horizontal direction to be in contact with a peripheral portion of the shower head 13. The shield member 101 has therein a multi-layer structure including a shield layer 102 made of a material having a permeability higher than that of aluminum. Further, a loading/unloading port 103 for loading/unloading a substrate W is disposed at the sidewall 10a. The loading/unloading port 103 is provided with a shutter 104 for opening and closing the loading/unloading port 103.

Similarly to the shield member 101, the shutter 104 has therein a multi-layer structure including a shield layer 105 made of a material having a permeability higher than that of aluminum. The shutter 104 is moved up and down by an elevating member 106 and a driving mechanism 107 to open and close the loading/unloading port 103. In other words, when the shutter 104 is closed, horizontal distances from a peripheral portion of the substrate support 11 to the shield member 101 and the shutter 104 are substantially the same. In other words, the distance from the plasma processing space 10s to a magnetic shield becomes uniform. Accordingly, an environmental magnetic field including terrestrial magnetism can be uniformly shielded along the entire circumference of the plasma processing chamber 10, and the deflection occurring when the magnetic field generated in the plasma processing space 10s is disturbed by the magnetic shield can be eliminated. Further, the plasma processing space 10s is in a state where the environmental magnetic field including terrestrial magnetism or horizontal magnetic field lines affected by other devices are shielded. Another opening/closing mechanism of the plasma processing chamber 10, such as a gate valve or the like, may have a multi-layer structure similar to that of the shutter 104.

At the bottom portion of the plasma processing chamber 10, an annular baffle plate 108 having a plurality of injection holes is disposed to surround the substrate support 11. The baffle plate 108 prevents plasma from leaking from the plasma processing space 10s to a gas outlet 10e. Further, the baffle plate 108 has therein a multi-layer structure including a shield layer 109 made of a material having a permeability higher than that of aluminum, similarly to the shield member 101 and the shutter 104.

The substrate support 11 includes a main body 111 and a ring assembly 112. The main body 111 has a central region (substrate supporting surface) 111a for supporting the substrate (wafer) W and an annular region (ring supporting surface) 111b for supporting the ring assembly 112. The annular region 111b of the main body 111 surrounds the central region 111a of the main body 111 in plan view. The substrate W is disposed on the central region 111a of the main body 111, and the ring assembly 112 is disposed on the annular region 111b of the main body 111 to surround the substrate W on the central region 111a of the main body 111. In one embodiment, the main body 111 includes a base and an electrostatic chuck. The base includes a conductive member. The conductive member of the base functions as a lower electrode. The electrostatic chuck is placed on the base. The upper surface of the electrostatic chuck has the substrate supporting surface 111a. The ring assembly 112 includes one or more annular members. At least one of the annular members is an edge ring. Although not shown, the substrate support 11 may include a temperature control module configured to adjust at least one of the electrostatic chuck, the ring assembly 112, and the substrate W to a target temperature. The temperature control module may include a heater, a heat transfer medium, a flow path, or a combination thereof. A heat transfer fluid such as brine or a gas flow through the flow path. Further, the substrate support 11 may include a heat transfer gas supply configured to supply a heat transfer gas to a gap between the backside of the substrate W and the substrate supporting surface 111a.

The shower head 13 is configured to introduce at least one processing gas from the gas supplier 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the gas inlet ports 13c. Further, the shower head 13 includes a conductive member. The conductive member of the shower head 13 functions as an upper electrode. The gas inlet portion may include, in addition to the shower head 13, one or a plurality of side gas injector (SGI) attached to one or a plurality of openings formed in the sidewall 10a.

The gas supplier 20 may include at least one gas source 21 and at least one flow rate controller 22. In one embodiment, the gas supplier 20 is configured to supply at least one processing gas from the corresponding gas source 21 to the shower head 13 through the corresponding flow rate controller 22. Each of the flow rate controllers 22 may include, e.g., a mass flow controller or a pressure-controlled flow rate controller. Further, the gas supplier 20 may include at least one flow rate modulation device for modulating the flow rate of at least one processing gas or causing it to pulsate.

The power supply 30 includes an RF power supply 31 connected to the plasma processing chamber 10 through at least one impedance matching circuit. The RF power supply 31 is configured to supply at least one RF signal (RF power), such as a source RF signal and a bias RF signal, to the conductive member of the substrate support 11 and/or the conductive member of the shower head 13. Accordingly, plasma is produced from at least one processing gas supplied to the plasma processing space 10s. Hence, the RF power supply 31 may function as at least a part of a plasma generator. By supplying the bias RF signal to the conductive member of the substrate support 11, a bias potential is generated at the substrate W, and ions in the produced plasma can be attracted to the substrate W.

In one embodiment, the RF power supply 31 includes a first RF generator 31a and a second RF generator 31b. The first RF generator 31a is connected to the conductive member of the substrate support 11 and/or the conductive member of the shower head 13 through at least one impedance matching circuit, to generate a source RF signal (source RF power) for plasma generation. In one embodiment, the source RF signal has a frequency within a range of 13 MHz to 150 MHz. In one embodiment, the first RF generator 31a may be configured to generate multiple source RF signals having different frequencies. One or multiple source RF signals so generated are supplied to the conductive member of the substrate support 11 and/or the conductive member of the shower head 13. The second RF generator 31b is connected to the conductive member of the substrate support 11 through at least one impedance matching circuit, and is configured to generate a bias RF signal (bias RF power). In one embodiment, the bias RF signal has a frequency lower than that of the source RF signal. In one embodiment, the bias RF signal has a frequency within a range of 400 kHz to 13.56 MHz. In one embodiment, the second RF generator 31b may be configured to generate multiple bias RF signals having different frequencies. One or multiple bias RF signals so generated are supplied to the conductive member of the substrate support 11. In various embodiments, at least one of the source RF signal and the bias RF signal may pulsate.

The power supply 30 may include a DC power supply 32 connected to the plasma processing chamber 10. The DC power supply 32 includes a first DC generator 32a and a second DC generator 32b. In one embodiment, the first DC generator 32a is connected to the conductive member of the substrate support 11 and is configured to generate a first DC signal. The first DC signal so generated is applied to the conductive member of the substrate support 11. In one embodiment, the first DC signal may be applied to another electrode, such as an electrode in an electrostatic chuck. In one embodiment, the second DC generator 32b is connected to the conductive member of the shower head 13 and is configured to generate a second DC signal. The second DC signal so generated is applied to the conductive member of the shower head 13. In various embodiments, the first and second DC signals may pulsate. The first and second DC generator 32a and 32b may be provided in addition to the RF power supply 31, and the first DC generator 32a may be provided instead of the second RF generator 31b.

The exhaust system 40 may be connected to, a gas outlet 10e disposed at a bottom of the plasma processing chamber 10, for example. The exhaust system 40 may include a pressure control valve and a vacuum pump. The pressure control valve adjusts a pressure in the plasma processing space 10s. The vacuum pump may include a turbo molecular pump, a dry pump, or a combination thereof.

(Structure of Shield Member)

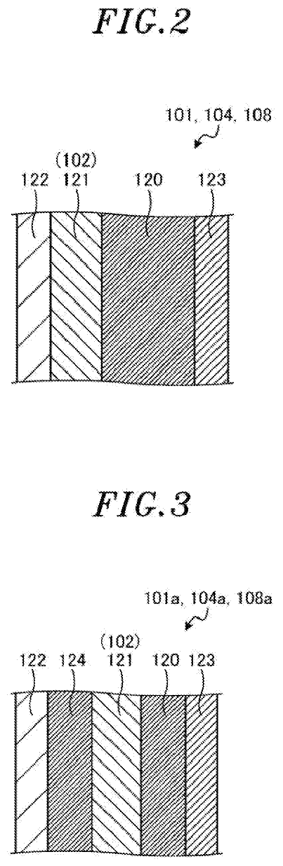

Next, the structures of the shield member 101, the shutter 104, and the baffle plate 108 will be described with reference to FIGS. 2 to 7. In the following description, among the shield member 101, the shutter 104, and the baffle plate 108, the structure of the shield member 101 will be described.

FIGS. 2 to 7 schematically show examples of the structure of the shield member in the present embodiment. As shown in FIG. 2, the shield member 101 has a shield layer 121 and a protective film 122 that are formed on a surface of a base material 120 that is exposed to plasma. Further, the shield member 101 has an anodic oxide film 123 formed on a surface the base material 120 that is not exposed to plasma. In other words, the shield member 101 has a multi-layer structure including the base material 120, the shield layer 121, the protective film 122, and the anodic oxide film 123. The base material 120 is a layer made of an aluminum-containing material such as an aluminum alloy or the like, and ensures a mechanical strength.

The shield layer 121 corresponds to the shield layers 102, 105, and 109 shown in FIG. 1, and is made of a material having a permeability higher than that of aluminum, such as Permalloy or the like. The shield layer in the following description is described to correspond to the shield layer 102, however, the shield layer in the following description may be correspond to the shield layers 105 and 109. The shield layer 121 is formed on the base material 120 by spraying, deposition, thin plate (sheet material) bonding, or the like. The bonding includes mechanical bonding, chemical bonding (adhesion), and metallurgical bonding (welding). Here, aluminum has a permeability μ≈1.257×10⁻⁶[H/m] and a relative permeability μ/μ₀≈1101.00, so that the shield layer 121 may be made of a material having a permeability and a relative permeability higher than those of aluminum. The material having a permeability higher than that of aluminum may be, e.g., the above-described Permalloy or electromagnetic steel (silicon steel). Permalloy has a permeability μ≈1.0×10⁻²[H/m] and a relative permeability μ/μ₀≈100000. Further, the electromagnetic steel (silicon steel) has a permeability μ≈5.0×10⁻³[H/m] and a relative permeability μ/μ₀≈4000. The shield layer 121 may be made of another material having a permeability higher than that of aluminum, such as iron (Fe), nickel (Ni), cobalt (Co), or an alloy thereof. A thickness of the shield layer 121 is adjusted appropriately depending on purposes because the shielding effect is improved as the shield layer 121 becomes thicker.

The protective film 122 is a plasma resistant layer and is an innermost layer of the shield member 101. The protective film 122 is, e.g., a film formed by thermal spraying, chemical vapor deposition (CVD) or physical vapor deposition (PVD). Further, the protective film 122 is, e.g., an oxide film, and may be a silicon-containing film. The oxide film includes an anodic oxide film. Further, the protective film 122 may be a film of a compound containing one or multiple elements among group III elements and lanthanoid-based elements. Here, one or multiple elements among yttrium, scandium and lanthanum can be used as the group III element. Further, one or multiple elements among cerium, dysprosium, and europium can be used as the lanthanoid-based element. Further, one or multiple compounds among yttria (Y₂O₃), SC₂O₃, Sc₂F₃, YF₃, La₂O₃, CeO₂, Eu₂O₃, and DyO₃ can be used as the compound. Further, the protective film 122 is preferably made of a material that does not generate particles during plasma processing.

In the case of forming the protective film 122 by thermal spraying, the protective film 122 is formed by ceramic thermal spraying, for example. In the ceramic thermal spraying, for example, a ceramic thermal spray coating film is formed by thermal spray coating using ceramic such as an oxide containing the above-described elements. After the spray coating, sintering and annealing may be performed. By forming the protective film 122 at the inner side of the shield layer 121, the shield layer 121 is embedded between the base material 120 and the protective film 122. Therefore, a material having a high permeability, such as Permalloy or the like, that cannot be used due to the problems of metal contamination, electrical characteristics, thermal conductivity, and the like can be used in the plasma processing chamber 10.

Further, the multi-layer structure of the shield member 101 may have the structure of a shield member 101a shown in FIG. 3. The shield member 101a includes the shield layer 121 (corresponding to the shield layer 102) formed on the surface of the base material 120 that is exposed to plasma, a cover layer 124 made of an aluminum-containing material such as an aluminum alloy or the like similarly to the base material 120, and the protective film 122. Further, in the shield member 101a, the anodic oxide film 123 is formed on the surface of the base material 120 that is not exposed to plasma, similarly to the shield member 101. The arrangement of the base material 120 and the cover layer 124 in the multi-layer structure may be changed. In other words, the shield layer 121 is embedded between the base material 120, such as an aluminum alloy or the like, and the cover layer 124. In the shield member 101a, even if the protective film 122 is peeled off, the metal contamination caused by the exposure of the shield layer 121 to the plasma processing space 10s can be prevented by the cover layer 124 or the base material 120. A shutter 104a and a baffle plate 108a also have a multi-layer structure to correspond to the shield member 101a.

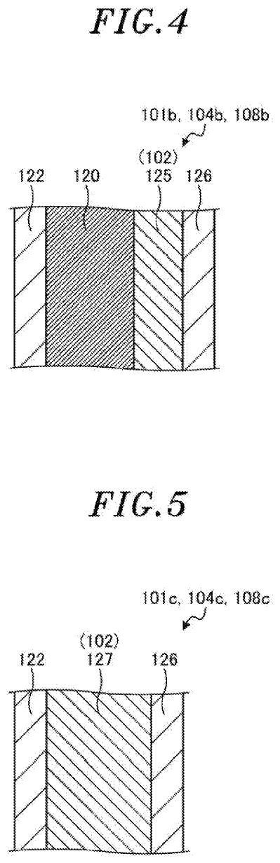

Further, the multi-layer structure of the shield member 101 may have the structure of the shield member 101b shown in FIG. 4. The shield member 101b has the protective film 122 formed on the surface of the base material 120 that is exposed to plasma. Further, the shield member 101b has a shield layer 125 (corresponding to the shield layer 102) and a protective film 126 formed on the surface of the base material 120 that is not exposed to plasma. Similarly to the shield layer 121, the shield layer 125 is made of a material having a permeability higher than that of aluminum, such as Permalloy or the like. The shield layer 125 is formed on the base material 120 by thermal spraying, vapor deposition, film adhesion, or the like. Similarly to the protective film 122, the protective film 126 (e.g., a ceramic thermal spray coating film or the like) is formed by thermal spraying, CVD, or PVD. In other words, in the shield member 101b, the shield layer 125 is located on the surface of the base material 120 that is not exposed to plasma, so that an anodic oxide film caused by aluminum of the base material 120 cannot be formed on that surface. Therefore, the protective film 126 is formed, instead of the anodic oxide film, on the surface of the shield layer 125 that is not exposed to plasma. The shutter 104b and the baffle plate 108b also have a multi-layer structure to correspond to the shield member 101b.

Further, the multi-layer structure of the shield member 101 may have the structure of the shield member 101c shown in FIG. 5. In the shield member 101c, a shield layer 127 (corresponding to the shield layer 102) is used as a base material, and the protective film 122 is formed on the surface of the shield layer 127 that is exposed to plasma. Further, the protective film 126 is formed on the surface of the shield layer 127 that is not exposed to plasma. Similarly to the shield layer 121, the shield layer 127 is made of a material having a permeability higher than that of aluminum, such as Permalloy or the like. As in the case of the shield member 101b, the protective films 122 and 126 (e.g., a ceramic thermal spray coating film or the like) are formed by thermal spraying, CVD, or PVD. In the shield member 101c, the shield layer 127 serves as a base material and has a large thickness, so that the magnetic shielding effect can be further improved. The shutter 104c and the baffle plate 108c also have a multi-layer structure to correspond to the shield member 101c.

Further, the multi-layer structure of the shield member 101 may have the structure of a shield member 101d shown in FIG. 6. In the shield member 101d, a sintered body 128 is used as a base material, and the shield layer 125 (corresponding to the shield layer 102), a cover layer 129 made of an aluminum-containing material such as an aluminum alloy or the like, and the anodic oxide film 123 are formed on the surface of the sintered body 128 that is not exposed to plasma. Further, at the surface of the sintered body 128 that is exposed to plasma, the sintered body 128 itself provide functions similar to the protective film 122. In other words, the sintered body 128 is a plasma resistant layer, and is made of ceramic such as an oxide containing the above-described various elements, or the like. The sintered body 128 may contain Si, SiO₂, or the like. Further, the sintered body 128 is a consumable material that is consumed by the exposure to the plasma of the plasma processing space 10s. When the sintered body 128 is consumed, the shield member 101d is replaced.

Similarly to the shield layer 121, the shield layer 125 is made of a material having a permeability higher than that of aluminum, such as Permalloy or the like. The shield layer 125 is formed on the sintered body 128 by thermal spraying, vapor deposition, film adhesion, or the like. The cover layer 129 is formed on the shield layer 125 by thermal spraying, vapor deposition, film adhesion, or the like. In the shield member 101d, the cover layer 129 is made of an aluminum-containing material such as an aluminum alloy or the like, so that the anodic oxide film 123 can be formed on the cover layer 129. Further, similarly to the protective film 122, a protective film such as a ceramic thermal spraying coating film may be formed, instead of the anodic oxide film 123, by thermal spraying, CVD or PVD. The shutter 104d and the baffle plate 108d also have a multi-layer structure to correspond to the shield member 101d.

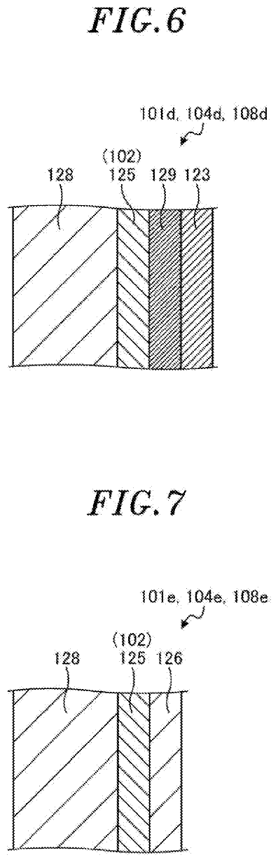

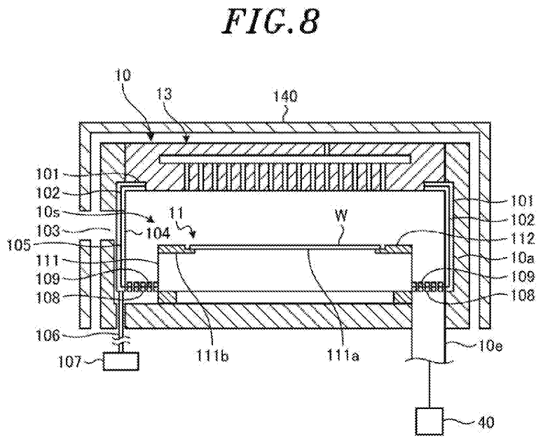

Further, the multi-layer structure of the shield member 101 may be similar to that of a shield member 101e shown in FIG. 7. In the shield member 101e, the sintered body 128 is used as a base material, and the shield layer 125 (corresponding to the shield layer 102) and the protective film 126 are formed on the surface of the sintered body 128 that is not exposed to plasma. Further, the surface of the sintered body 128 that is exposed to plasma has the same function as that of the protective film 122, similarly to the shield member 101d. Similarly to the shield member 101d, the shield layer 125 is made of a material having a permeability higher than that of aluminum, such as Permalloy or the like. The shield layer 125 is formed on the sintered body 128 by thermal spraying, vapor deposition, film adhesion, or the like. As in the case of the shield member 101b, the protective film 126 (e.g., a ceramic thermal spraying coating film or the like) is formed by spraying, CVD or PVD. In the shield member 101e, a layer made of an aluminum-containing material such as an aluminum alloy or the like is not used. In other words, when a sintered body or a bulk material such as SiO₂, Si, or SiC is used for a shield or a shutter member, a layer made of Permalloy or the like may be formed (coated) on the bulk material by thermal spraying, vapor deposition, film adhesion, or the like. The shutter 104e and the baffle plate 108e also have a multi-layer structure to correspond to the shield member 101e.

(Addition of Magnetic Shield Cover)

In the present embodiment, in the plasma processing chamber 10, the shield member 101 is disposed at the inner side of the sidewall 10a. However, a magnetic shield cover for covering the plasma processing chamber 10 may be further provided. FIG. 8 shows an example of the magnetic shield cover in the present embodiment. As shown in FIG. 8, the cover 140 is disposed to cover the side surface and the upper surface of the plasma processing chamber 10. Further, the cover 140 has an opening formed at a position corresponding to the loading/unloading port 103, so that the substrate W can be loaded into and unloaded from the plasma processing chamber 10. The cover 140 is made of a material having a permeability higher than that of aluminum, such as Permalloy or the like. Further, the inner surface and the outer surface of the cover 140 may be coated with resin or painted to prevent scratches or contamination. By further providing the cover 140, the magnetic shielding effect can be further improved.

In the above-described embodiment, the shield layers 102 and 109 are disposed at a part of an upper portion of the shield member 101 that extends inward in the horizontal direction or disposed in the baffle plate 108. However, the shield layers 102 and 109 extending in the horizontal direction may be omitted. In other words, the magnetic field lines of the terrestrial magnetism or the magnetic field generated from other adjacent devices are mainly horizontal, so that the shield layers 102 and 109 extending in the horizontal direction may be omitted if the shielding can be sufficiently performed by the shield layers 102 and 105 extending in the vertical direction of the shield member 101 and the shutter 104.

In the above-described embodiment, the shield member 101 is disposed at the inner side of the sidewall 10a of the plasma processing chamber 10. However, the present disclosure is not limited thereto. For example, the sidewall 10a itself may serve as the shield member 101.

In accordance with the present embodiment, the plasma processing apparatus 1 includes the plasma processing container (the plasma processing chamber 10) whose wall (the sidewall 10a and the shield member 101) has a multi-layer structure including a layer made of a material having a permeability higher than that of aluminum, the loading/unloading port 103 disposed on the wall of the plasma processing chamber to load/unload the substrate W into/from the plasma processing chamber, and the substrate support 11 disposed in the plasma processing chamber. Accordingly, it is possible to shield the environmental magnetic field including terrestrial magnetism and magnetism from other devices. Further, it is possible to suppress the deflection of the magnetic field generated in the plasma processing space 10s.

Further, in accordance with the present embodiment, the loading/unloading port 103 has the shutter 104 having a multi-layer structure and configured to open/close the loading/unloading port 103. Hence, the loading/unloading port 103 can also shield the environmental magnetic field including terrestrial magnetism and magnetism from other devices.

Further, in accordance with the present embodiment, the multi-layer structure further includes a layer made of an aluminum-containing material. Accordingly, the thermal and electrical characteristics can be improved while reducing the weight of the plasma processing chamber 10.

Further, in accordance with the present embodiment, the multi-layer structure further includes a layer made of an oxide sintered body. Accordingly, the oxide sintered body can be used as the base material of the plasma processing chamber 10.

Further, in accordance with the present embodiment, the multi-layer structure is further formed on the surface where the plasma-resistant layer is exposed to plasma. Accordingly, the environmental magnetic field including terrestrial magnetism and magnetism from other devices can be shielded while preventing metal contamination of the plasma processing space 10s by the layer made of a material having a permeability than higher that of aluminum, such as Permalloy or the like.

Further, in accordance with the present embodiment, the multi-layer structure is further formed on the surface where the plasma resistant layer is not exposed to plasma. Accordingly, it is possible to prevent exposure of a layer made of a material having a permeability higher than that of aluminum, such as Permalloy or the like.

Further, in accordance with the present embodiment, the plasma resistant layer is an oxide film. Accordingly, it is possible to prevent exposure of the layer made of a material having a permeability higher than that of aluminum, such as Permalloy or the like.

Further, in accordance with the present embodiment, the plasma resistant layer is a silicon-containing film. Accordingly, it is possible to prevent exposure of the layer made of a material having a permeability higher than that of aluminum, such as Permalloy or the like.

Further, in accordance with the present embodiment, the plasma resistant layer is a film of a compound containing one or multiple elements among the group III elements and lanthanoid-based elements. Accordingly, it is possible to prevent exposure of the layer made of a material having a permeability higher than that of aluminum, such as Permalloy or the like.

Further, in accordance with the present embodiment, the plasma resistant layer is a film formed by thermal spraying, CVD, or PVD. Accordingly, it is possible to prevent exposure of the layer made of a material having a permeability higher than that of aluminum, such as Permalloy or the like.

Further, in accordance with the present embodiment, the plasma resistant layer is an anodic oxide film. Accordingly, the layer made of the aluminum-containing material can be protected.

Further, in accordance with the present embodiment, the multi-layer structure includes the plasma resistant layer (the protective film 122), the layer having a permeability higher than that of aluminum (the shield layer 121), the layer made of an aluminum-containing material (the base material 120), and the anodic oxide film 123 in that order from the surface exposed to plasma. Accordingly, it is possible to shield the environmental magnetic field including terrestrial magnetism and magnetism from other devices.

Further, in accordance with the present embodiment, the multi-layer structure includes the plasma resistant layer (the protective film 122) and the layer made of a first aluminum-containing material (the cover layer 124), the layer made of a material having a permeability higher than that of aluminum (the shield layer 121), the layer made of a second aluminum-containing material (the base material 120), and the anodic oxide film 123 in that order from the surface exposed to plasma. Accordingly, it is possible to shield the environmental magnetic field including terrestrial magnetism and magnetism from other devices.

Further, in accordance with the present embodiment, the material having a permeability higher than that of aluminum is Permalloy. Accordingly, it is possible to shield the environmental magnetic field including terrestrial magnetism and magnetism from other devices.

Further, in accordance with the present embodiment, the material having a permeability higher than that of aluminum is electrical steel. Accordingly, it is possible to shield the environmental magnetic field including terrestrial magnetism and magnetism from other devices.

Further, in accordance with the present embodiment, the plasma processing apparatus further includes the cover made of a material having a permeability higher than that of aluminum and configured to cover the plasma processing chamber. Hence, it is possible to shield the environmental magnetic field including terrestrial magnetism and magnetism from other devices.

The embodiments of the present disclosure are illustrative in all respects and are not restrictive. The above-described embodiments may be omitted, replaced, or changed in various forms without departing from the scope of the appended claims and the gist thereof.

In the above-described embodiment, the capacitively coupled plasma processing apparatus 1 for performing processing such as etching or the like on the substrate W using capacitively coupled plasma as a plasma source has been described as an example. However, the present disclosure is not limited thereto. The plasma source is not limited to the capacitively coupled plasma as long as an apparatus processes the substrate W using plasma, and any plasma source such as inductively coupled plasma, microwave plasma, magnetron plasma, or the like may be used.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A plasma processing apparatus comprising:
a plasma processing chamber whose wall has a multi-layer structure including a layer made of a material having a permeability higher than a permeability of aluminum;
a loading/unloading port disposed on the wall of the plasma processing chamber to load/unload a substrate into/from the plasma processing chamber; and
a substrate support disposed in the plasma processing chamber.

2. The plasma processing apparatus of claim 1, wherein the loading/unloading port is provided with a shutter having a multi-layer structure and configured to open/close the loading/unloading port.

3. The plasma processing apparatus of claim 1, wherein the multi-layer structure further includes a layer made of an aluminum-containing material.

4. The plasma processing apparatus of claim 1, wherein the multi-layer structure further includes a layer made of an oxide sintered body.

5. The plasma processing apparatus of claim 1, wherein the multi-layer structure further includes a plasma resistant layer formed on a surface exposed to plasma.

6. The plasma processing apparatus of claim 1, wherein the multi-layer structure further includes a plasma resistant layer formed on a surface which is not exposed to plasma.

7. The plasma processing apparatus of claim 5, wherein the multi-layer structure further includes a plasma resistant layer formed on a surface which is not exposed to plasma.

8. The plasma processing apparatus of claim 5, wherein the plasma resistant layer is an oxide film.

9. The plasma processing apparatus of claim 5, wherein the plasma resistant layer is a silicon-containing film.

10. The plasma processing apparatus of claim 5, wherein the plasma resistant layer is a film of a compound containing one or more of group III elements and lanthanoid-based elements.

11. The plasma processing apparatus of claim 5, wherein the plasma resistant layer is a film formed by thermal spraying, chemical vapor deposition (CVD), or physical vapor deposition (PVD).

12. The plasma processing apparatus of claim 5, wherein the plasma resistant layer is an anodic oxide film.

13. The plasma processing apparatus of claim 5, wherein the multi-layer structure includes the plasma resistant layer, the layer made of the material having a permeability higher than a permeability of aluminum, a layer made of an aluminum-containing material, and an anodic oxide film in that order from the surface exposed to plasma.

14. The plasma processing apparatus of claim 5, wherein the multi-layer structure includes the plasma resistant layer, a layer made of a first aluminum-containing material, the layer made of the material having a permeability higher than a permeability of aluminum, a layer made of a second aluminum-containing material, and an anodic oxide film in that order from the surface exposed to plasma.

15. The plasma processing apparatus of claim 1, wherein the material having a permeability higher than a permeability of aluminum is Permalloy.

16. The plasma processing apparatus of claim 1, wherein the material having a permeability higher than a permeability of aluminum is electrical steel.

17. The plasma processing apparatus of claim 1, further comprising:
a cover made of a material having a permeability higher than a permeability of aluminum and configured to cover the plasma processing chamber.
